(19) United States
(12) Patent Application Publication
(10) Pub. No.: US 2008/0180948 A1
(43) Pub. Date: Jul. 31, 2008

(54) White light emitting device and light source module for liquid crystal display backlight using the same

(75) Inventors: Chul Soo Yoon, Suwon (KR); Il Woo Park, Suwon (KR); Jong Rak Sohn, Suwon (KR); Chang Hoon Kwak, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/003,814

(22) Filed: Jan. 2, 2008

(30) Foreign Application Priority Data
Jan. 2, 2007 (KR) 10-2007-352

(51) Int. Cl. H01L 33/00

(52) U.S. Cl. 362/230; 257/98; 257/E33.061

(57) ABSTRACT

A white light emitting device including: a blue LE chip having a dominant wavelength of 430 to 455 nm; a red phosphor disposed around the blue light emitting diode chip, the red phosphor excited by the blue light emitting diode chip to emit red light; and a green phosphor disposed around the blue light emitting diode chip, the green phosphor excited by the blue LED chip to emit green light, wherein the red light emitted from the red phosphor has a color coordinate falling within a space defined by four coordinate points (0.5448, 0.4544), (0.7079, 0.2920), (0.6427, 0.2905) and (0.4794, 0.4633) based on the CIE 1931 chromaticity diagram, the green light emitted from the green phosphor has a color coordinate falling within a space defined by four coordinate points (0.1270, 0.8037), (0.4117, 0.5861), (0.4197, 0.5316) and (0.2555, 0.5030) based on the CIE 1931 color chromaticity diagram, and the red phosphor includes a phosphor represented by (Sr, Ba, Ca)AlSiN₃:Eu and the green phosphor includes a phosphor represented by (Sr, Ba, Ca)₂SiO₄:Eu.

### CROSS-REFERENCE TO RELATED APPLICATIONS

This application claims the priority of Korean Patent Application No. 2007-00352 filed on Jan. 2, 2007, in the Korean Intellectual Property Office, the disclosure of which is incorporated herein by reference.

### BACKGROUND OF THE INVENTION

1. Field of the Invention

The present invention relates to a white light emitting device and a light source module for a liquid crystal display (LCD) backlight, more particularly, to a white light emitting device improved in color reproducibility and material stability and a light source module for an LCD backlight using the same.

2. Description of the Related Art

Recently, a white light emitting device having a light emitting diode (LED) has gained attention as a light source for a liquid crystal display (LCD) backlight, in place of an existing fluorescent lamp or a small lamp. Generally, the white light emitting device can be obtained by combining a blue LED and a yellow phosphor. For example, the white light emitting device may be manufactured by applying a yellow phosphor (or a resin containing the yellow phosphor) such as YAG, TAG, and BOSE on the InGaN-based LED. Here, blue light emitted from the LED and yellow light emitted from the phosphor such as YAG are combined together to output white light.

FIG. 1A is a graph illustrating an emission spectrum of a conventional white light emitting device. This emission spectrum is obtained from the white light emitting device including a blue LED and a YAG-based yellow phosphor excited by the blue LED. As shown in FIG. 1A, the spectrum exhibits relatively low intensity at a long wavelength, thus ill-affecting color reproducibility.

FIG. 1B illustrates spectrums obtained when the white light of FIG. 1 is transmitted to blue, green and red filters, respectively. As shown in FIG. 1B, the red light filtered by the red filter has a considerably low intensity at a wavelength of at least 600 nm.

FIG. 2 is a 1931 CIE chromaticity diagram which shows color reproducibility of an LCD which employs an array of the white light emitting device having a spectrum of FIG. 1A as a backlight source module. Referring to FIG. 2, the LCD represents 55 to 65% color reproducibility with respect to the National Television System Committee (NTSC) standard. Here, a triangular space A represented by the LCD accounts for 55 to 56% with respect to an NTSC-based triangular space. This level of color reproducibility does not allow various colors to be reproduced into near-natural colors.

Furthermore, to realize the white light emitting device, in addition to the aforesaid combination of the blue LED and yellow phosphor, the blue LED, and red and green phosphors have been combined together. These red and green phosphors used increase color reproducibility moderately but not sufficiently. Also, the red or green phosphor for use in the white light emitting device is so unstable as a phosphor material as to be impaired by external energy, thereby not assuring a reliable product.

In a conventional white light source module for the BLU, a blue LED, a green LED and a red LED are arranged on a circuit board. FIG. 3 illustrates an example of such arrangement. Referring to FIG. 3, a white light source module 10 for a BLU includes a red R LED 12, a green G LED 14 and a blue LED 16 arranged on a circuit board 11 such as a printed circuit board. The R, G, and B LEDs 12, 14, and 16 may be mounted on the board 11 in a configuration of packages each including an LED chip of a corresponding color, or lamps. These R, G, and B LED packages or lamps may be repeatedly arranged on the board to form an over all white surface or line light source. As described above, the white light source module 10 employing the R, G, and B LEDs is relatively excellent in color reproducibility and an overall output light can be controlled by adjusting a light amount of the R, G, and B LEDs.

However, in the white light source module 10 described above, the R, G, and B LEDs 12, 14, and 16 are spaced apart from another, thereby potentially posing a problem to color uniformity. Moreover, to produce white light of a unit area, at least a set of R, G, and B LED chips is required since the three-colored LED chips constitute a white light emitting device. This entails complicated circuit configuration for driving and controlling the LED of each color, thus leading to higher costs for circuits. This also increases the manufacturing costs for packages and the number of the LEDs required.

Alternatively, to implement a white light source module, a white light emitting device having a blue LED and a yellow phosphor has been employed. The white light source module utilizing a combination of the blue LED and yellow phosphor is simple in circuit configuration and low in price. However, the white light source module is poor in color reproducibility due to relatively low light intensity at a long wavelength. Therefore, a higher-quality and lower-cost LCD requires a white light emitting device capable of assuring better color reproducibility, and a white light source module using the same.

Accordingly, there has been a call for maximum color reproducibility and stable color uniformity of the white light emitting device adopting the LED and phosphor, and the white light source module using the same.

### SUMMARY OF THE INVENTION

An aspect of the present invention provides a white light emitting device improved in color reproducibility and excellent in material stability.

An aspect of the present invention also provides a white light emitting device with high color reproducibility and superior color uniformity.

According to an aspect of the present invention, there is provided a white light emitting device including: a blue LED chip having a dominant wavelength of 430 to 455 nm; a red phosphor disposed around the blue LED chip, the red phosphor excited by the blue LED chip to emit red light; and a green phosphor disposed around the blue LED chip, the green phosphor excited by the blue LED chip to emit green light, wherein the red light emitted from the red phosphor has a color coordinate falling within a space defined by four coordinate points (0.5448, 0.4544), (0.7079, 0.2920), (0.6427, 0.2905) and (0.4794, 0.4633) based on the CIE 1931 chromaticity diagram, the green light emitted from the green phosphor has a color coordinate falling within a space defined by four coordinate points (0.1270, 0.8037), (0.4117, 0.5861), (0.4197, 0.5316) and (0.2555, 0.5030) based on the CIE 1931 color chromaticity diagram, and the red phosphor includes a phosphor represented by (Sr, Ba, Ca)AlSiN₃:Eu and the green phosphor includes a phosphor represented by (Sr, Ba, Ca)₂SiO₄:Eu.

The blue LED chip may have a full width at half-maximum of 10 to 30 nm, the green phosphor may have a full width at half-maximum of 30 to 100 nm and the red phosphor may have a full width at half-maximum of 50 to 200 nm.

The red phosphor may have a peak wavelength of 600 to 650 nm, and the green phosphor may have a peak wavelength of 500 to 550 nm.

The green phosphor may include at least one of SrGa₂S₄:Eu and β—SiAlON(Beta-SiAlON).

The red phosphor may further include a phosphor represented by SrₓBa_{y}Ca_{z}S:Eu, where 0≦x, y, z≦2.

According to another aspect of the present invention, there is provided a light source module for a liquid crystal display backlight including: a circuit board; and a plurality of white light emitting devices disposed on the circuit board, wherein each of the white light emitting devices includes: a blue LED chip disposed on the circuit board and having a dominant wavelength of 430 to 455 nm; a red phosphor disposed around the blue LED chip, the red phosphor excited by the blue LED chip to emit red light; and a green phosphor disposed around the blue LED chip, the green phosphor excited by the blue LED chip to emit green light, wherein the red light emitted from the red phosphor has a color coordinate falling within a space defined by four coordinate points (0.5448, 0.4544), (0.7079, 0.2920), (0.6427, 0.2905) and (0.4794, 0.4633) based on the CIE 1931 color chromaticity diagram, the green light emitted from the green phosphor has a color coordinate falling within a space defined by four coordinate points (0.1270, 0.8037), (0.4117, 0.5861), (0.4197, 0.5316) and (0.2555, 0.5030) based on the CIE 1931 color chromaticity diagram, and the green phosphor is represented by (Sr, Ba, Ca)AlSiN₃:Eu and the green phosphor is represented by (Sr, Ba, Ca)₂SiO₄:Eu.

### BRIEF DESCRIPTION OF THE DRAWINGS

The above and other aspects, features and other advantages of the present invention will be more clearly understood from the following detailed description taken in conjunction with the accompanying drawings, in which:

FIG. 1A illustrates an emission spectrum of a conventional white light emitting device and FIG. 1B illustrates emission spectrums obtained by filtering output light of a conventional white light emitting device by blue, green and red color filters, respectively;

FIG. 2 is a chromaticity diagram illustrating color reproducibility of a liquid crystal display (LCD) which adopts a conventional white light emitting device as a backlight;

FIG. 3 is a cross-sectional view illustrating a conventional white light source module for a backlight unit;

FIG. 4 illustrates an emission spectrum of a white light emitting device according to an exemplary embodiment of the invention;

FIG. 5 illustrates spectrums obtained by filtering the white light emitting device of FIG. 4 by blue, green and red color filters;

FIG. 6 is a chromaticity diagram illustrating color reproducibility of an LCD which adopts the white light emitting device of FIG. 4 as a backlight;

FIG. 7 illustrates an emission spectrum of a white light emitting device according to another exemplary embodiment of the invention;

FIG. 8 is a side cross-sectional view schematically illustrating a white light emitting device according to an exemplary embodiment of the invention;

FIG. 9 is a side cross-sectional view schematically illustrating a white light emitting device according to another exemplary embodiment of the invention;

FIG. 10 is a side cross-sectional view schematically illustrating a light source module for an LCD backlight according to an exemplary embodiment of the invention;

FIG. 11 is a side cross-sectional view schematically illustrating a light source module for an LCD backlight according to another exemplary embodiment of the invention;

FIG. 12 illustrates a color coordinate space of phosphors used in a white light emitting device according to an exemplary embodiment of the invention;

FIG. 13 illustrates a color coordinate range obtained in a case where white light source modules of Inventive Example and Comparative Example are employed in a backlight unit of an LCD;

FIG. 14 is a cross-sectional view illustrating a white light emitting device and a white light source module according to an exemplary embodiment of the invention; and

FIG. 15 is a cross-sectional view illustrating a white light emitting device and a white light source module according to another exemplary embodiment of the invention.

### DETAILED DESCRIPTION OF THE PREFERRED EMBODIMENT

Exemplary embodiments of the present invention will now be described in detail with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference signs are used to designate the same or similar components throughout.

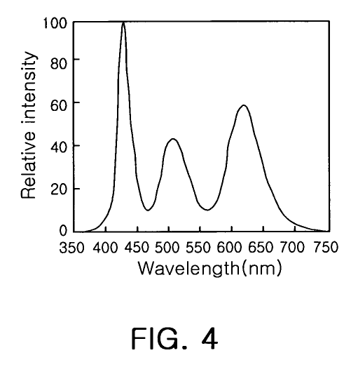

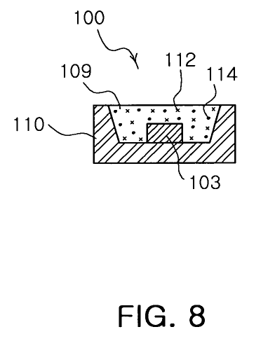

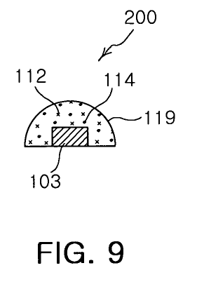

FIG. 4 illustrates an emission spectrum of a white light emitting diode (LED) device according to an exemplary embodiment of the invention. The emission spectrum of FIG. 4 is obtained from the white light emitting device which adopts a combination of a blue LED, a red phosphor represented by AAlSiN₃:Eu, where A is at least one selected from Ba, Sr and Ca, and a silicate green phosphor represented by A₂SiO₄:Eu, where A is at least one selected from Ba, Sr and Ca. Particularly, the emission spectrum of FIG. 4 may be obtained by utilizing an InGaN-based blue LED, CaAlSiN₃:Eu as the red phosphor and Sr_{0.4}Ba_{1.6}SiO₄:Eu as the green phosphor. This InGaN-based blue LED, the red phosphor represented by SrₓBa_{y}Ca_{1-x-y}SiO₄:Eu, where 0≦x+y≦1 and 0≦x, y≦1, and the red phosphor represented by SrₘBaₙCa₂₋ₘ₋ₙAlSiN₃:Eu, where 0≦m+n≦2, and 0≦m, m≦2 have an emission peak of 425 to 460 nm, 500 to 550 nm and 600 to 650 nm, respectively depending on a compositional ratio of x, y and m, n. The white light emitting device can be specifically configured as shown in FIGS. 8 and 9 below.

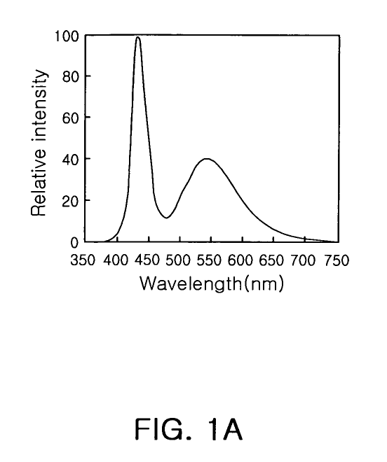

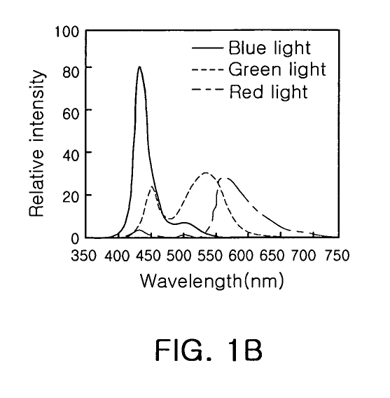

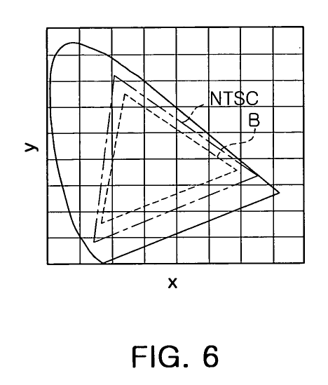

Referring to FIG. 4, contrary to the conventional emission spectrum shown in FIG. 1A, the emission spectrum exhibits sufficient light intensity at a red and green wavelength. Notably, the spectrum demonstrates sufficiently high light intensity in a long-wavelength visible ray region. Moreover, in the emission spectrum, blue, green and red regions (RGB) have an emission peak in a range of 425 to 460 nm, 500 to 550 nm, and 600 to 650 nm, respectively. The emission peak of the green region has a relative intensity of about 40% with respect to that of the blue region, and the emission peak of the red region has a relative intensity of about 60%. These emission peaks of three primary colors and corresponding relative intensity described above serve to bring about very high reproducibility (see FIG. 6).

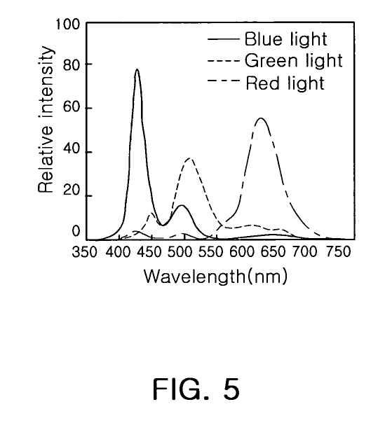

FIG. 5 illustrates spectrums obtained by filtering white light having an emission spectrum of FIG. 4 by blue, green and red color filters of an LCD. As shown in FIG. 5, the spectrums, i.e., blue light, green light and red light spectrums filtered by each filter of three primary colors, have an emission peak and corresponding relative intensity substantially similar to the spectrum of the white light (see FIG. 4). That is, the blue, green and red light spectrums obtained after being filtered by the respective color filters are only shifted insignificantly in emission peak and exhibit emission peaks substantially identical to the emission peaks (425 to 460 nm, 500 to 550 nm, and 600 to 650 nm) of the pre-filtered white light in the RGB regions. Furthermore, relative intensity of the RGB light filtered by the color filters at each peak is substantially identical to the relative intensity of the white light at each peak. Therefore, three primary colors of light obtained after being filtered by the color filters ensure various colors to be reproduced into near-natural colors.

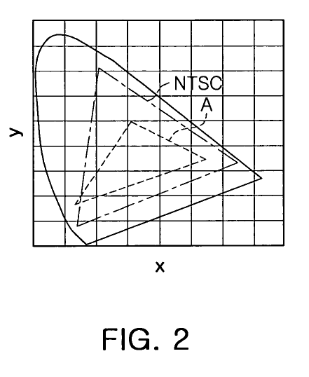

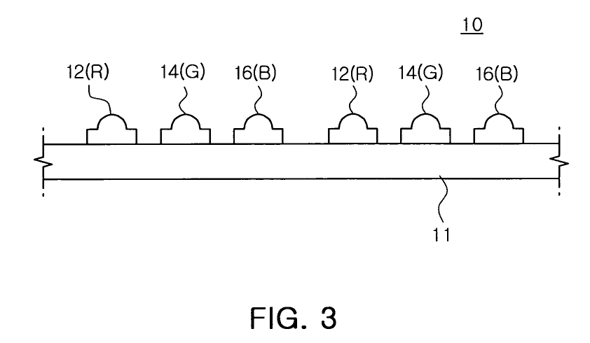

FIG. 6 is a 1931 CIE chromaticity diagram. FIG. 6 illustrates color reproducibility of an LCD which employs a white light emitting device having an emission spectrum of FIG. 4 as a backlight. As shown in FIG. 6, in a case where the white light of FIG. 4 is employed as the LCD backlight, the LCD produces a considerably larger area of a triangular color coordinate space B than a conventional triangular color coordinate space (see FIG. 2). This triangular color coordinate space B represents about 80% color reproducibility with respect to the NTSC standard. This is about 20% increase from the conventional color reproducibility (55 to 65%) as shown in FIG. 2, and thus construed as a remarkable improvement in color reproducibility.

AAlSiN₃:Eu (where A is at least one of Ba, Sr and Ca) as the nitride red phosphor, and A₂SiO₄:Eu (where A is at least one selected from Ba, Sr and Ca) as the silicate green phosphor combined with the blue LED may be varied in composition. For example, Ca in CaAlSiN₃:Eu may be at least partially substituted by at least one of Sr and Ba. This allows red emission peak of the white light and relative intensity at the red emission peak to be adjusted within a certain range.

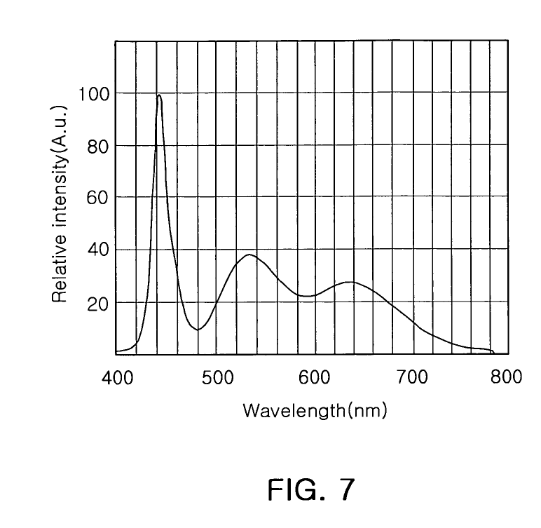

FIG. 7 illustrates an emission spectrum of a white light emitting device according to another exemplary embodiment of the invention. Notably, the spectrum of FIG. 7 is obtained from the white light emitting device which adopts an InGaN-based blue LED, SrAlSiN₃:Eu as a red phosphor and Sr_{0.4}Ba_{1.6}SiO₄:Eu as a green phosphor. As shown in FIG. 7, a compositional change may alter the emission peak slightly and relative intensity at each peak. However, the spectrum demonstrates an emission peak having a relative intensity of at least 20% in a long-wavelength visible ray region, thus serving to improve color reproducibility. When the white light is produced by combining the blue LED, a nitride red phosphor represented by AAlSiN₃:Eu, where A is at least one of Ba, Sr and Ca and a silicate green phosphor represented by A₂SiO₄:Eu, where A is at least one selected from Ba, Sr and Ca, the whit light can be improved in color reproducibility by at least 10% over the conventional white light utilizing a yellow phosphor (see FIG. 1A).

FIG. 8 is a cross-sectional view schematically illustrating a white light emitting device according to an exemplary embodiment of the invention. Referring to FIG. 8, the white light emitting device 100 includes a package body 110 having a reflective cup formed in a center thereof and a blue LED 103 disposed on a bottom of the reflective cup. A transparent resin encapsulant 109 is formed in the reflective cup to encapsulate the blue LED 103. The resin encapsulant 109 may adopt e.g., a silicon resin or an epoxy resin. In the resin encapsulant 109, particles of the nitride red phosphor 12 represented by AAlSiN₃:Eu (where A is at least one selected from Ba, Sr and Ca) and particles of the silicate green phosphor 114 represented by A₂SiO₄:Eu (where A is at least one selected from Ba, Sr and Ca) are evenly dispersed. A connecting conductor (not shown) such as leads is formed on the bottom of the reflective cup and connected to the blue LED 103 by wire bonding or flip-chip bonding.

Blue light emitted from the blue LED 103 excites the nitride red phosphor 112 represented by AAlSiN₃:Eu and the silicate green phosphor 114 represented by A₂SiO₄:Eu so that the red phosphor 112 and the green phosphor 114 emit red light and green light, respectively. The red phosphor 112 may be excited by the green light emitted from the silicate green phosphor 114.

The nitride red phosphor 112 represented by AAlSiN₃:Eu and the silicate green phosphor 114 represented by A₂SiO₄:Eu can be excited with relative high efficiency at a wavelength of 430 to 455 nm, and thus the blue LED 103 may have a peak wavelength of 425 to 460 nm. Moreover, to realize optimal color reproducibility, the nitride red phosphor 112 and the silicate green phosphor 114 may have a peak wavelength of 500 to 550 nm and 600 to 650 nm, respectively.

The white light emitting device 100 is improved in color reproducibility and stable as a phosphor material as described above. AAlSiN₃:Eu as the red phosphor 112 and A₂SiO₄:Eu as the green phosphor 114 are relatively strong against temperature and humidity, and hardly degraded by reaction with a curing accelerator such as Pt added to the resin encapsulant 109. In fact, when subjected to an operational reliability test at a high temperature and high humidity, AAlSiN₃:Eu as the nitride-based phosphor and A₂SiO₄:Eu as the silicate phosphor are highly stable compared to the conventional yellow phosphor.

FIG. 9 illustrates a white light emitting device according to another exemplary embodiment of the invention. Referring to FIG. 9, the white light emitting device 200 includes a resin encapsulant with an upwardly domed lens, e.g., a semi-circular lens, and a blue LED 103 encapsulated by the resin encapsulant. The aforesaid nitride red phosphor 112 and the silicate green phosphor 114 are dispersed in the resin encapsulant 119. In the present embodiment, an additional package body with a reflective cup is not provided but a very wide angle of view can be attained. Also, the blue LED 103 can be directly mounted on a circuit board.

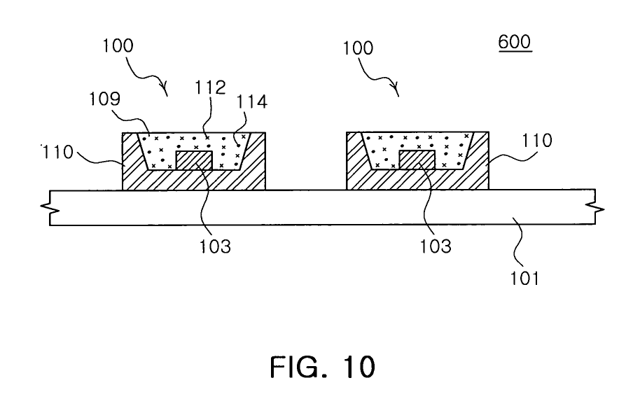

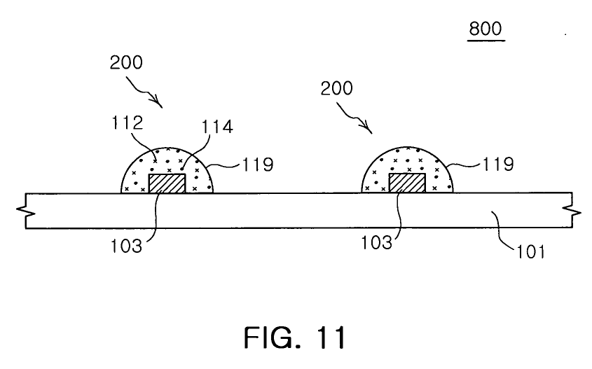

FIGS. 10 and 11 are side cross-sectional views schematically illustrating a light source module for an LCD backlight according to an exemplary embodiment of the invention, respectively. The light source module may be associated with several optical members such as a diffusion plate, light guide plate, reflective plate and prism sheet as a light source of the LCD backlight unit to constitute a backlight assembly.

Referring to FIG. 10, the light source module for the LCD backlight 600 includes a circuit board 101 and a plurality of white light emitting devices 100 arranged on the circuit board 101. A conductive pattern (not shown) may be formed on the circuit board 101 to connect to the light emitting device 100. As has been described with reference to FIG. 8, each of the white light emitting devices 100 includes a blue LED chip 103 mounted on a reflective cup of the package body 110 and a resin encapsulant 109 encapsulating the blue LED chip 103. A nitride red phosphor 112 and the silicate green phosphor 114 are dispersed in the resin encapsulant 109.

Referring to FIG. 11, a light source module for an LCD backlight 800 includes a circuit board 101 and a plurality of white light emitting devices 200 arranged on the circuit board 101. In the present embodiment, the blue LED 103 is directly mounted on the circuit board 101 by a chip-on-board (COB) technique. Each of the white light emitting devices 200 is configured as described with reference to FIG. 9. Here, a semi-circular lens (resin encapsulant 119) is formed without additional reflective wall provided, allowing the white light emitting device 200 to have a wider angle of view. The wider angle of view of the white light source also leads to decrease in size (thickness or width) of the LCD.

The white light emitting device 200 includes a blue B light emitting diode (LED) chip 103, a green G phosphor 114 and a red R phosphor 112. The green phosphor 114 and the red phosphor 112 are excited by the blue LED chip 103 to emit green light and red light, respectively. The green light and the red light are mixed with a portion of the blue light from the blue LED chip 103 to produce white light.

Particularly, according to the present embodiment, the blue LED chip 103 is directly mounted on the circuit board 101 and the phosphors 112 and 114 are dispersed and mixed uniformly in a resin encapsulant 119 encapsulating the blue LED chip 103. The resin encapsulant 119 may be formed, for example, in a semi-circle which serves as a kind of lens. Alternatively, the resin encapsulant 119 may be formed of one of an epoxy resin, a silicon resin and a hybrid resin. As described above, the blue LED chip 103 is directly mounted on the circuit board 101 by a chip-on-board technique, thereby allowing the white light emitting device 200 to achieve a greater angle of view more easily.

One of an electrode pattern and a circuit pattern (not shown) is formed on the circuit board 101, and the circuit pattern is connected to an electrode of the blue LED chip 103 by e.g., wire bonding or flip-chip bonding. This white light source module 800 may include a plurality of the white light emitting devices 200 to form a surface or line light source with a desired area, thereby beneficially utilized as a light source of a backlight unit of the LCD.

The inventors of the present invention have defined a dominant wavelength of the blue LED chip 103 to be in a specific range and a color coordinate of the red and green phosphors 112 and 114 to be within a specific space based on the CIE 1931 color chromaticity diagram. This enabled the inventors to realize maximum color reproducibility from a combination of the green and red phosphors and the blue LED chip.

Specifically, to obtain maximum color reproducibility from a combination of the blue LED chip-green phosphor-red phosphor, the blue LED chip 103 has a dominant wavelength of 430 to 455 nm. Also, the red light emitted from the red phosphor 107 excited by the blue LED chip 103 has a color coordinate falling within a space defined by four coordinate points (0.5448, 0.4544), (0.7079, 0.2920), (0.6427, 0.2905) and (0.4794, 0.4633) based on the CIE 1931 (x, y) color chromaticity diagram. Moreover, the green light emitted from the green phosphor excited by the blue LED chip 103 has a color coordinate falling within a space defined by (0.1270, 0.8037), (0.4117, 0.5861), (0.4197, 0.5316) and (0.2555, 0.5030) based on the CIE 1931 color chromaticity diagram.

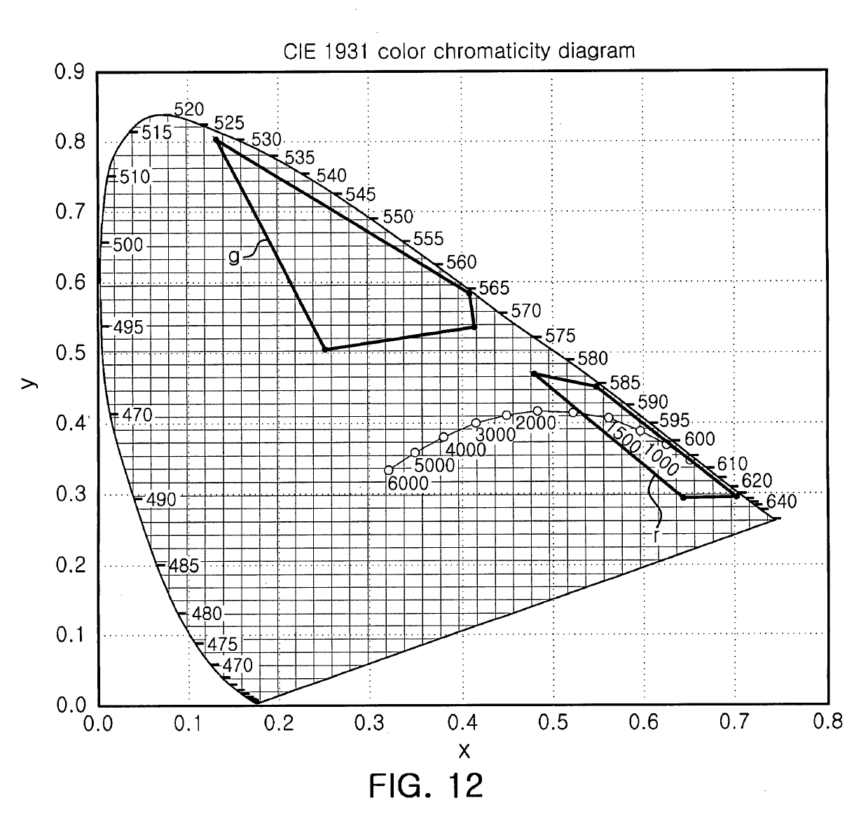

FIG. 12 illustrates color coordinate spaces of the red and green phosphors described above. Referring to FIG. 12, the CIE 1931 color chromaticity diagram is marked with a quadrilateral-shaped space r composed of four coordinate points (0.5448, 0.4544), (0.7079, 0.2920), (0.6427, 0.2905) and (0.4794, 0.4633) and a quadrilateral-shaped space g composed of four coordinate points (0.1270, 0.8037), (0.4117, 0.5861), (0.4197, 0.5316) and (0.2555, 0.5030). As described above, the red phosphor and green phosphor are selected such that color coordinates thereof fall within the quadrilateral-shaped spaces r and g, respectively.

Here, a dominant wavelength is a wavelength value derived from a curve obtained by integrating an actually-measured spectrum graph of an output light of the blue LED chip and a luminosity curve. The dominant wavelength is a value considering visibility of a person. This dominant wavelength corresponds to a wavelength value at a point where a line connecting a center point (0.333, 0.333) of the CIE 1976 color chromaticity diagram to the actually-measured color coordinate meets a contour line of the CIE 1976 chromaticity diagram. It should be noted that a peak wavelength is different from the dominant wavelength. The peak wavelength has the highest energy intensity. The peak wavelength is a wavelength value indicating the highest intensity in the spectrum graph of the actually-measured output light, regardless of luminosity.

Here, the blue LED chip 103 has a dominant wavelength of 430 to 455 nm. The red phosphor 112 has a color coordinate falling within a quadrilateral space defined by four coordinate points (0.5448, 0.4544), (0.7079, 0.2920), (0.6427, 0.2905) and (0.4794, 0.4633), based on the CIE 1931 color chromaticity diagram. The green phosphor 114 represented by SrₓBa_{y}Ca_{z}SiO₄:Eu, where 0≦x, y, z≦2, has a color coordinate falling within a quadrilateral space defined by four coordinate points (0.1270, 0.8037), (0.4117, 0.5861), (0.4197, 0.5316) and (0.2555, 0.5030). Accordingly, a liquid crystal display (LCD) employing the white light source module 510 for a backlight unit may exhibit high color reproducibility across a very large color coordinate space covering a substantially entire s-RGB space on the CIE 1976 chromaticity diagram (see FIG. 12). This high color reproducibility is hardly attainable from a conventional combination of a blue LED chip and red and green phosphors.

The blue LED chip and red and green phosphors falling outside the dominant wavelength range and color coordinate space as described above may degrade color reproducibility or color quality of the LCD. Conventionally, the blue LED chip used along with the red and green phosphors to obtain white light has a dominant wavelength of typically 460 nm or more. However, according to the present embodiment, the blue light has a shorter dominant wavelength than the conventional one and the red and green phosphors have a color coordinate falling within the quadrilateral space as described above, thereby producing higher color reproducibility which is hardly achieved by the prior art.

The blue LED chip 103 may adopt a group-III nitride semiconductor light emitting device in general use. Also, the red phosphor 112 may utilize a nitride phosphor such as (Sr, Ba, Ca)AlSiN₃:Eu. This nitride red phosphor is less vulnerable to the external environment such as heat and humidity than a yellow phosphor, and less likely to be discolored. Notably, the nitride red phosphor exhibits high excitation efficiency with respect to the blue LED chip having a dominant wavelength set to a specific range of 430 to 455 nm to obtain high color reproducibility. Alternatively, the red phosphor 112 may contain other nitride phosphor such as Ca₂Si₅N₈:Eu or a yellow phosphor such as AS:Eu, where A is at least one selected from Ba, Sr and Ca.

The green phosphor 105 may adopt a silicate phosphor including (Sr, Ba, Ca)₂SiO₄:Eu, where A is at least one selected from Ba, Sr and Ca. For example, the green phosphor 105 may employ (Ba, Sr)₂SiO₄:Eu. The silicate phosphor demonstrates high excitation efficiency with respect to the blue LED chip having a dominant wavelength of 430 to 455 nm. Alternatively, one of SrGa₂S₄:Eu and β—SiAlON(Beta-SiAlON) may be utilized as the green phosphor 114.

Particularly, the blue LED chip 103 has a full width at half maximum (FWHM) of 10 to 30 nm, the green phosphor 114 has a FWHM of 30 to 100 nm, and the red phosphor 112 has a FWHM of 50 to 200 nm. The light sources 103, 112, and 114 with the FWHM ranging as described above produces white light of better color uniformity and higher color quality. Especially, the blue LED chip 103 having a dominant wavelength of 430 to 455 nm and a FWHM of 10 to 30 nm significantly enhances excitation efficiency of the (Sr, Ba, Ca)AlSiN₃:Eu red phosphor and (Sr, Ba, Ca)₂SiO₄:Eu green phosphor.

According to the present embodiment, the blue LED chip has a dominant wavelength of a predetermined range and the green and red phosphors have color coordinates within a predetermined space. This allows superior color reproducibility than a conventional combination of the blue LED chip and yellow phosphor, and than a conventional combination of the blue LED chip and green and red phosphors, respectively. This also improves excitation efficiency and overall light efficiency as well.

Furthermore, according to the present embodiment, unlike the conventional white light source module using the red, green and blue LED chips, a fewer number of LED chips are required and only one type of the LED chip, i.e., blue LED chip is required. This accordingly reduces manufacturing costs for packages and simplifies a driving circuit. Notably, an additional circuit may be configured with relative simplicity to increase contrast or prevent blurring. Also, only one LED chip 103 and the resin encapsulant encapsulating the LED chip 109 and 119 allow white light of a unit area to be emitted, thereby ensuring superior color uniformity to a case where the red, green and blue LED chips are employed.

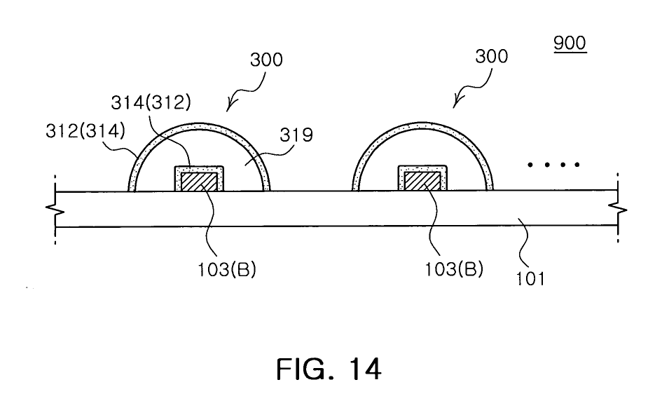

FIG. 14 is schematic cross-sectional view illustrating a white light emitting device 900 and a white light source module 520 using the same. In the embodiment of FIG. 14, a blue LED chip 103 is directly mounted on a circuit board 101 by a chip-on-board technique. The blue LED chip 103 constitutes the white light emitting device 200 of a unit area together with a red phosphor and a green phosphor excited by the blue LED chip 103. Moreover, to achieve maximum color reproducibility, the blue LED chip 103 has a dominant wavelength range, and the red phosphor and green phosphor have a color coordinate space as described above, respectively. That is, the blue LED chip 103 has a dominant wavelength of 430 to 455 nm. The red phosphor has a color coordinate falling within a quadrilateral space defined by four coordinate points (0.5448, 0.4544), (0.7079, 0.2920), (0.6427, 0.2905) and (0.4794, 0.4633) on the CIE 1931 color chromaticity diagram. The green phosphor has a color coordinate falling within a quadrilateral space defined by four coordinate points (0.1270, 0.8037), (0.4117, 0.5861), (0.4197, 0.5316) and (0.2555, 0.5030).

However, according to the present embodiment, the red and green phosphors are not dispersed and mixed in a resin encapsulant but provided as a phosphor film 312 and 314. Specifically, as shown in FIG. 14, a green phosphor film 314 containing the green phosphor is thinly applied along a surface of the blue LED chip 103 and a semi-circular transparent resin encapsulant 319 is formed on the green phosphor film 314. Also, a red phosphor film 312 containing the red phosphor is applied on a surface of the transparent resin encapulant 319. The green phosphor film 314 and the red phosphor film 312 may be located reversely with each other. That is, the red phosphor film 312 may be applied on the blue LED chip 103 and the green phosphor film 314 may be applied on the resin encapsulant 319. The green phosphor film 314 and the red phosphor film 312 may be formed of a resin containing green phosphor particles and red phosphor particles, respectively. The phosphors contained in the phosphor films 312 and 314 may employ one of a nitride, a yellow phosphor and a silicate phosphor as described above.

As described above, in the white light emitting device 300, the green phosphor film 314, the transparent resin encapsulant 319, and the red phosphor film 312 are formed to further enhance color uniformity of white light outputted. When the green and red phosphors (powder mixture) are merely dispersed in the resin encapsulant, the phosphors are not uniformly distributed due to difference in weight between the phosphors during resin curing, thus risking a problem of layering. This may reduce color uniformity in a single white light emitting device. However, in a case where the green phosphor film 314 and the red phosphor film 312 separated by the resin encapsulant 319 are adopted, the blue light emitted at various angles from the blue LED chip 103 are relatively uniformly absorbed or transmitted through the phosphor films 312 and 314, thereby producing more uniform white light overall. That is, color uniformity is additionally enhanced.

Also, as shown in FIG. 14, the phosphor films 312 and 314 separate from each other by the transparent resin encapsulant 319 may lower phosphor-induced optical loss. In a case where the phosphor powder mixture is dispersed in the resin encapsulant, secondary light (green light or red light) wavelength-converted by the phosphor is scattered by phosphor particles present on an optical path, thereby causing optical loss. However, in the embodiment of FIG. 14, the secondary light wavelength-converted by the thin green or red phosphor film 314 or 312 passes through the transparent resin encapsulant 230 or is emitted outside the light emitting device 300, thereby lowering optical loss resulting from the phosphor particles.

In the embodiment of FIG. 14, the blue LED chip has a dominant wavelength range, and the green and red phosphors have color coordinate space as described above, respectively. Accordingly, the white light source module 900 for the BLU of the LCD exhibits high color reproducibility across a very large space covering a substantially entire s-RGB space. This also reduces the number of the LED chips, and manufacturing costs for driving circuits and packages, thereby realizing lower unit costs. Of course, the blue, green and red light may have a FWAH ranging as described above.

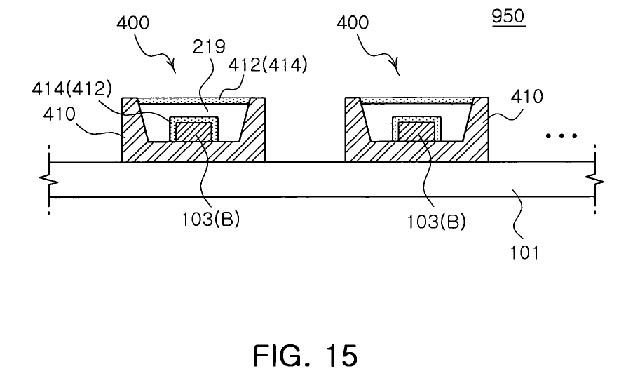

In the present embodiments described above, each of LED chips is directly mounted on the circuit board by a COB technique. However, the present invention is not limited thereto. For example, the LED chip may be mounted inside a package body mounted on the circuit board. FIG. 15 illustrates additional package bodies employed according to an exemplary embodiment of the invention, respectively.

FIG. 15 is a schematic cross-sectional view illustrating a white light emitting device 400 and a white light source module 950 using the same according to an exemplary embodiment of the invention. Referring to FIG. 15, the white light emitting device 400 includes a package body 410 defining a reflective cup and a blue LED chip 103 mounted on the reflective cup.

However, according to the present embodiment, the red and green phosphors are not dispersed and mixed in a resin encapsulant and provided as a phosphor film. That is, one of a green phosphor 414 and a red phosphor 412 is applied along a surface of the blue LED chip 103 and a transparent resin encapsulant 419 is formed thereon. Also, the other one of the green and red phosphors 412 and 414 is applied along a surface of the transparent resin encapsulant 419.

As in the embodiment of FIG. 14, in the embodiment of FIG. 15, the green phosphor film 414 and the red phosphor film 412 separated from each other by the resin encapsulant 419 are employed to ensure superior color uniformity. Also, in the same manner as the aforesaid embodiments, the blue LED chip has a dominant wavelength range and the red and green phosphors have color coordinate spaces as described above, thereby producing high color reproducibility across a very large space covering a substantially entire s-RGB space.

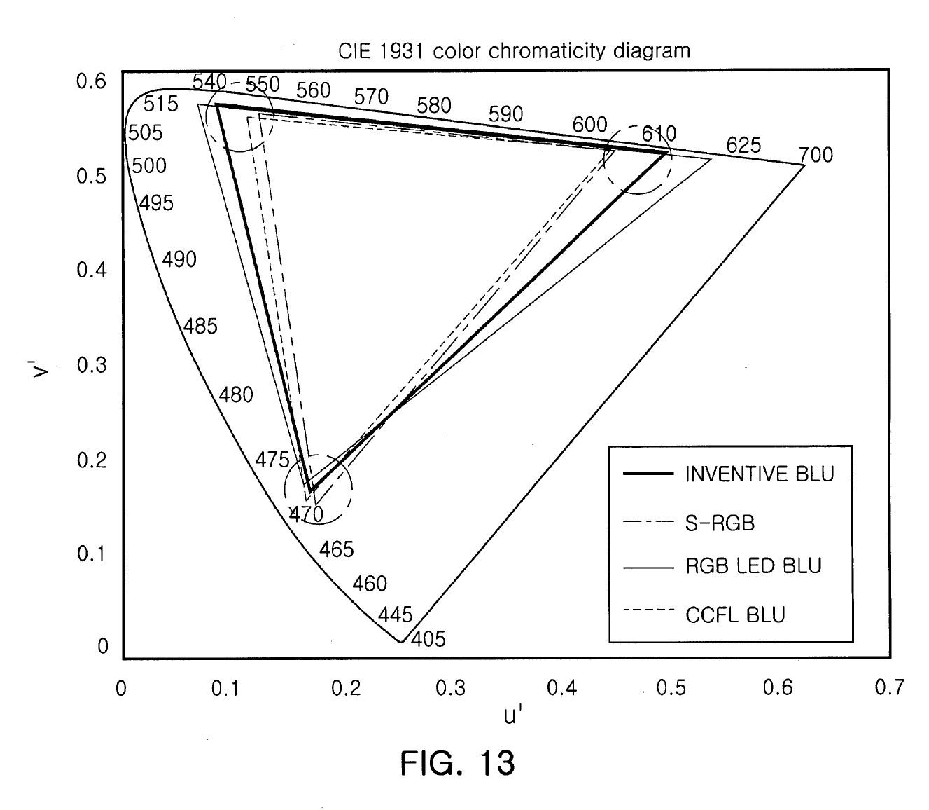

FIG. 13 illustrates the CIE 1976 chromatic diagram indicating color coordinate ranges obtained in a case where white light source modules of Inventive Example and Comparative Example are employed in BLUs of LCDs, respectively.

Referring to FIG. 13, the white light source module of Inventive Example emits white light by a combination of a blue LED chip, a red phosphor and a green phosphor (see FIG. 10). In the white light source of Inventive Example, the blue LED chip has a dominant wavelength of 430 to 455 nm, particularly 445 nm. Also, the red phosphor emits red light having a color coordinate falling within a quadrilateral space defined by four coordinate points (0.5448, 0.4544), (0.7079, 0.2920), (0.6427, 0.2905) and (0.4794, 0.4633) based on the CIE 1931 color chromaticity diagram. The green phosphor emits green light having a color coordinate falling within a quadrilateral space defined by (0.1270, 0.8037), (0.4117, 0.5861), (0.4197, 0.5316) and (0.2555, 0.5030) based on the CIE 1931 color chromaticity diagram.

Meanwhile, the white light source module of Comparative Example 1 emits white light by a combination of red, green and blue LED chips. Also, a white light source module of Comparative Example 2 emits white light using a conventional cold cathode fluorescent lamp.

The chromaticity diagram of FIG. 13 indicates a color coordinate space of the LCD employing the light source module of Inventive Example as the BLU, and a color coordinate space of the LCDs employing the light sources of Comparative Example 1 and Comparative Example 2 as the BLUs, respectively. As shown in FIG. 13, the LCD adopting the BLU according to Inventive Example exhibits a very broad color coordinate space covering a substantially entire s-RGB space. This high color reproducibility is not attainable by a conventional combination of a blue LED chip, red and green phosphors.

The LCD utilizing the BLU (RGB LED BLU) according to Comparative Example 1 employs only the LED chips as red, green and blue light sources, thus demonstrating a broad color coordinate space. However, as shown in FIG. 13, the LCD adopting the RGB LED BLU according to Comparative Example 1 disadvantageously does not exhibit a blue color in the s-RGB space. Also, only three-color LED chips employed without phosphors degrade color uniformity, while increasing the number of the LED chips required and manufacturing costs. Notably, this entails complicated configuration of an additional circuit for contrast increase or local dimming, and drastic increase in costs for the circuit configuration.

As shown in FIG. 13, the LCD employing the BLU (CCFL BLU) of Comparative Example 2 exhibits a relatively narrow color coordinate space, thus lowered in color reproducibility over the BLUs of Inventive Example and Comparative Example 1, respectively. Moreover, the CCFL BLU is not environment-friendly and can be hardly configured in a circuit for improving its performance such as local dimming and contrast adjustment.

In the aforesaid embodiments, the nitride red phosphor represented by (Sr, Ba, Ca)AlSiN₃:Eu and the silicate green phosphor represented by (Sr, Ba, Ca)₂SiO₄:Eu are dispersed in the resin encapsulant but the present invention is not limited thereto. For example, the red and green phosphors may be provided as a layer (phosphor layer or layers) formed on a surface of the blue LED. Here, two types of phosphors may be combined in a phosphor layer and each phosphor may be configured as a separate layer structure.

As set forth above, according to exemplary embodiments of the invention, a blue LED chip having a dominant wavelength of a specific range, and red and green phosphors having a color coordinate of a specific space, respectively, are employed. This assures high color reproducibility which is hardly realized by a conventional combination of a blue LED chip, red and green phosphors. This also results in superior color uniformity and reduces the number of the LEDs necessary for a light source module for a BLU, and costs for packages and circuit configuration. In consequence, this easily produces a higher-quality and lower-cost white light source module and a backlight unit using the same.

While the present invention has been shown and described in connection with the exemplary embodiments, it will be apparent to those skilled in the art that modifications and variations can be made without departing from the spirit and scope of the invention as defined by the appended claims.

What is claimed is:

1. A white light emitting device comprising:
a blue light emitting diode chip having a dominant wavelength of 430 to 455 nm;
a red phosphor disposed around the blue light emitting diode chip, the red phosphor excited by the blue light emitting diode chip to emit red light; and
a green phosphor disposed around the blue light emitting diode chip, the green phosphor excited by the blue light emitting diode chip to emit green light,
wherein the red light emitted from the red phosphor has a color coordinate falling within a space defined by four coordinate points (0.5448, 0.4544), (0.7079, 0.2920), (0.6427, 0.2905) and (0.4794, 0.4633) based on the CIE 1931 chromaticity diagram,
the green light emitted from the green phosphor has a color coordinate falling within a space defined by four coordinate points (0.1270, 0.8037), (0.4117, 0.5861), (0.4197, 0.5316) and (0.2555, 0.5030) based on the CIE 1931 color chromaticity diagram, and
the red phosphor comprises a phosphor represented by (Sr, Ba, Ca)AlSiN₃:Eu and the green phosphor comprises a phosphor represented by (Sr, Ba, Ca)₂SiO₄:Eu.

2. The white light emitting device of claim 1, wherein the blue light emitting diode chip has a full width at half-maximum of 10 to 30 nm, the green phosphor has a full width at half-maximum of 30 to 100 nm and the red phosphor has a full width at half-maximum of 50 to 200 nm.

3. The white light emitting device of claim 1, wherein the red phosphor has a peak wavelength of 600 to 650 nm, and the green phosphor has a peak wavelength of 500 to 550 nm.

4. The white light emitting device of claim 1, wherein the green phosphor comprises at least one of SrGa₂S₄:Eu and β—SiAlON(Beta-SiAlON).

5. The white light emitting device of claim 1, wherein the red phosphor further comprises a phosphor represented by SrₓBa_{y}Ca_{z}S:Eu, where 0≦x, y, z≦2.

6. A light source module for a liquid crystal display backlight comprising:
a circuit board; and
a plurality of white light emitting devices disposed on the circuit board,
wherein each of the white light emitting devices comprises:
a blue light emitting diode chip disposed on the circuit board and having a dominant wavelength of 430 to 455 nm;
a red phosphor disposed around the blue light emitting diode chip, the red phosphor excited by the blue light emitting diode chip to emit red light; and
a green phosphor disposed around the blue light emitting diode chip, the green phosphor excited by the blue light emitting diode chip to emit green light,
wherein the red light emitted from the red phosphor has a color coordinate falling within a space defined by four coordinate points (0.5448, 0.4544), (0.7079, 0.2920), (0.6427, 0.2905) and (0.4794, 0.4633) based on the CIE 1931 color chromaticity diagram,
the green light emitted from the green phosphor has a color coordinate falling within a space defined by four coordinate points (0.1270, 0.8037), (0.4117, 0.5861), (0.4197, 0.5316) and (0.2555, 0.5030) based on the CIE 1931 color chromaticity diagram, and
the green phosphor is represented by (Sr, Ba, Ca)AlSiN₃:Eu and the green phosphor is represented by (Sr, Ba, Ca)₂SiO₄:Eu.
